(19) United States
(12) Patent Application Publication
(10) Pub. No.: US 2024/0088064 A1
(43) Pub. Date: Mar. 14, 2024

(54) SEMICONDUCTOR DEVICE

(71) Applicant: Mitsubishi Electric Corporation, Tokyo (JP)

(72) Inventor: Daichi OTORI, Tokyo (JP)

(73) Assignee: Mitsubishi Electric Corporation, Tokyo (JP)

(21) Appl. No.: 18/346,505

(22) Filed: Jul. 3, 2023

(30) Foreign Application Priority Data
Sep. 8, 2022 (JP) 2022-142983

(51) Int. Cl. H01L 23/00; H01L 23/29; H01L 23/31; H01L 23/498; H01L 25/11; H01L 25/18

(52) U.S. Cl. CPC H01L 23/564; H01L 23/296; H01L 23/3121; H01L 23/49811; H01L 23/49844; H01L 25/115; H01L 25/18; H01L 21/56

(57) ABSTRACT

Provided is a semiconductor device with improved humidity resistance in which deformation of a substrate and a casing caused by expansion and contraction of a sealant cured in manufacturing processes is reduced. The semiconductor device includes: an insulating substrate; first and second circuit patterns formed on one surface of the insulating substrate; a first terminal electrode electrically connected to the first circuit pattern; first and second semiconductor elements mounted on the first circuit pattern; a second terminal electrode electrically connected to the first and second semiconductor elements through the second circuit pattern; a first sealant covering the first semiconductor element; a second sealant covering the second semiconductor element and made of a material different from that of the first sealant; and a casing enclosing the first and second semiconductor elements, separated from the first and second semiconductor elements, and bonded to the insulating substrate.

### BACKGROUND OF THE INVENTION

### Field of the Invention

The present disclosure relates to a semiconductor device.

### DESCRIPTION OF THE BACKGROUND ART

In conventional semiconductor devices, casings of the semiconductor devices are filled with plastics and semiconductor elements are sealed with plastics, for example, to protect the semiconductor elements and provide humidity resistance. Thus, when the semiconductor devices operate, the heat generated from the semiconductor elements sometimes deform the sealing plastics and warp the semiconductor devices. To address these, Japanese Patent Application Laid-Open No. 2020-107666 discloses a technology for reducing warpage of a semiconductor device which is caused by heat generated in a semiconductor element by continuously increasing a linear expansion coefficient of a sealing plastic from the semiconductor element to a top surface of the sealing plastic. Moreover, Japanese Patent Application Laid-Open No. 2006-351737 discloses a technology for sealing an entire module by locally covering each of semiconductor elements or collectively a group of nearby semiconductor elements with an epoxy-based plastic and further overlaying the upper portion with urethane plastic.

However, the technologies do not consider expansion and contraction of the sealing plastic in processes of manufacturing the semiconductor device. Thus, there has been a problem in that the expansion and contraction of the sealing plastic cured in the manufacturing processes may deform a substrate and a casing of the semiconductor device. When the substrate and the casing are deformed, it is feared that, for example, insufficient contact between the semiconductor device and a heat sink may lead to a decrease in heat dissipation or the substrate and the casing may be cracked in providing a tight fit between the semiconductor device and the heat sink. In Japanese Patent Application Laid-Open No. 2006-351737 above, each or the group of the semiconductor elements is locally sealed with the epoxy-based plastic and the surrounding area is sealed with urethane plastic, so that the entire casing is sealed with plastics. Thus, expansion and contraction of the cured sealing plastics may deform the substrate and the casing of the semiconductor device. If urethane sealing is eliminated, the sealing plastic is thinned more than conventional sealing plastics. This makes it difficult to protect the semiconductor elements and provide humidity resistance.

### SUMMARY

The present disclosure has an object of providing a semiconductor device with improved humidity resistance in which deformation of a substrate and a casing caused by expansion and contraction of a sealant cured in manufacturing processes is reduced.

A semiconductor device according to an aspect of the present disclosure includes: an insulating substrate; a first circuit pattern formed on one surface of the insulating substrate; a second circuit pattern formed on the one surface of the insulating substrate; a first terminal electrode electrically connected to the first circuit pattern; a first semiconductor element mounted on the first circuit pattern; a second semiconductor element mounted on the first circuit pattern, the second semiconductor element being different from the first semiconductor element; a second terminal electrode electrically connected to the first semiconductor element and the second semiconductor element through the second circuit pattern; a first sealant covering the first semiconductor element; a second sealant covering the second semiconductor element, the second sealant being made of a material different from a material of the first sealant; and a casing enclosing the first semiconductor element and the second semiconductor element, the casing being separated from the first sealant and the second sealant and being bonded to the insulating substrate.

The present disclosure can produce a semiconductor device with improved humidity resistance in which deformation of a substrate and a casing caused by expansion and contraction of a cured sealant is reduced.

These and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view of a semiconductor device according to Embodiment 1;

FIG. 2 is a schematic cross-sectional view of a semiconductor device according to Embodiment 2;

FIG. 3 is a schematic top view of a semiconductor device before a first sealant and a second sealant are formed according to Embodiments 1 and 2;

FIG. 4 is a schematic top view of the semiconductor device in which a first jig has been set, according to Embodiment 2;

FIG. 5 is a schematic top view of the semiconductor device in which the first sealant has been injected into the first jig, according to Embodiment 2;

FIG. 6 is a schematic top view of the semiconductor device in which a second jig has been set, according to Embodiment 2;

FIG. 7 is a schematic top view of the semiconductor device in which the second sealant has been injected into the second jig, according to Embodiment 2;

FIG. 8 is a schematic top view of the semiconductor device after the first sealant and the second sealant have been formed, according to Embodiment 2;

FIG. 9 is a schematic cross-sectional view of a semiconductor device according to Embodiment 3;

FIG. 10 is a schematic cross-sectional view of a semiconductor device according to Embodiment 4;

FIG. 11 is a schematic cross-sectional view of a semiconductor device according to Embodiment 5;

FIG. 12 is a schematic cross-sectional view of a semiconductor device according to Embodiment 6; and

FIG. 13 is a schematic cross-sectional view of a semiconductor device according to Embodiment 7.

### DESCRIPTION OF THE PREFERRED EMBODIMENTS

The following will describe example semiconductor devices according to the present disclosure. The present disclosure is not limited to Embodiments below, but can be variously modified and implemented without departing from the spirit and scope of the present disclosure.

### Embodiment 1

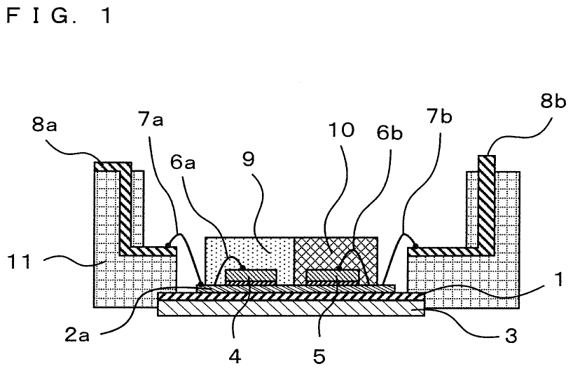

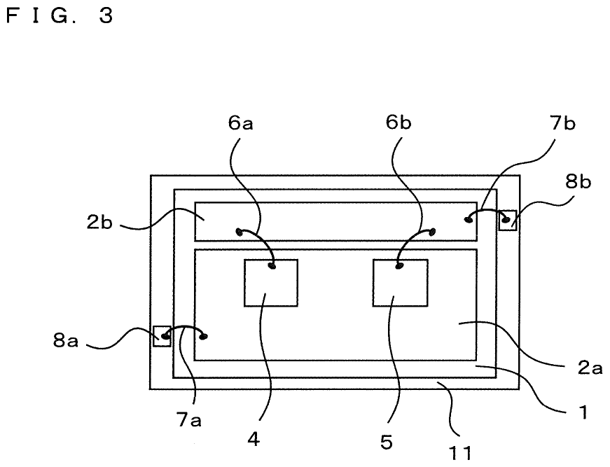

FIG. 1 is a schematic cross-sectional view of a semiconductor device according to Embodiment 1. FIG. 3 is a schematic top view of a semiconductor device before a first sealant 9 and a second sealant 10 are formed according to Embodiments 1 and 2. As illustrated in FIGS. 1 and 3, a first circuit pattern 2a and a second circuit pattern 2b are formed on one of surfaces of an insulating substrate 1, and a base plate 3 that is a heat spreader is formed on the other surface of the insulating substrate 1 in the semiconductor device according to Embodiment 1. A first semiconductor element 4 and a second semiconductor element 5 different from the first semiconductor element 4 are mounted on the first circuit pattern 2a. The first semiconductor element 4 is electrically connected to the second circuit pattern 2b through a lead 6a, and the second semiconductor element 5 is electrically connected to the second circuit pattern 2b through a lead 6b. Furthermore, the first circuit pattern 2a is electrically connected to a terminal electrode 8a through a control wire 7a. The second circuit pattern 2b is electrically connected to a ten iinal electrode 8b through a control wire 7b. The first semiconductor element 4 is covered with the first sealant 9, and the second semiconductor element 5 is covered with the second sealant 10 made of a material different from that of the first sealant 9. The semiconductor device further includes a casing 11 which encloses the first semiconductor element 4 and the second semiconductor element 5, which is separated from the first sealant 9 and the second sealant 10, and which is bonded to the insulating substrate 1.

Placement of the first semiconductor element 4 and the second semiconductor element 5 different from the first semiconductor element 4 means placement of two semiconductor elements irrespective of, for example, type, structure, or drive voltage of the semiconductor elements. For example, irrespective of whether the types of the semiconductor elements are identical, the placement of two semiconductor elements includes a case where both of the first semiconductor element 4 and the second semiconductor element 5 are diodes and a case where one of the first semiconductor element 4 and the second semiconductor element 5 is a diode and the other is a transistor. Examples of the semiconductor elements include a discrete semiconductor and an integrated semiconductor. A combination of the first semiconductor element 4 and the second semiconductor element 5 is not restricted by, for example, the type, structure, or drive voltage of the semiconductor elements.

Furthermore, an appropriate material of a sealant can be selected for each of the semiconductor elements to be covered with the sealant to protect the semiconductor elements and improve the humidity resistance. Specifically, a material of a sealant which can, for example, protect the semiconductor elements and provide humidity resistance can be selected for each of the semiconductor elements so that the entire casing 11 need not be sealed with a plastic. For example, when a sealant for the first semiconductor element 4 requires higher adhesion and a sealant for the second semiconductor element 5 requires higher heat resistance, selecting application of an epoxy plastic to the first sealant 9 and application of a silicone plastic to the second sealant 10 is possible. This combination is merely illustrative, and a material of a sealant can be selected for each of the semiconductor elements to be covered with the sealant, depending on, for example, specifications required for the semiconductor elements and the semiconductor device. Examples of applicable materials of other constituent elements include a copper alloy for the base plate 3, and an engineering plastic for the casing 11. The materials of the constituent elements are not limited to the aforementioned materials, but can be arbitrarily combined depending on, for example, the specification and the required performance of the semiconductor device.

Furthermore, a high-molecular-weight compound layer (not illustrated) made of a material different from those of the first sealant 9 and the second sealant 10 may be formed on a surface of one of the first semiconductor element 4 and the second semiconductor element 5. For example, when the first sealant 9 is made of an epoxy plastic, applying polyimide to the surface of the first semiconductor element 4 as a high-molecular-weight compound layer can further improve humidity resistance more than that without the high-molecular-weight compound layer.

Application of a semiconductor device with such a structure can select a material of a sealant for each semiconductor element without filling the sealant into the entire casing. Thus, a semiconductor device with improved humidity resistance in which deformation of a substrate and a casing caused by expansion and contraction of the cured sealant is reduced can be provided.

Thus, application of the semiconductor device in Embodiment 1 can select a material of a sealant for each semiconductor element without filling the sealant into the entire casing. Thus, the semiconductor device with improved humidity resistance in which deformation of the substrate and the casing caused by expansion and contraction of the cured sealant is reduced can be obtained.

### Embodiment 2

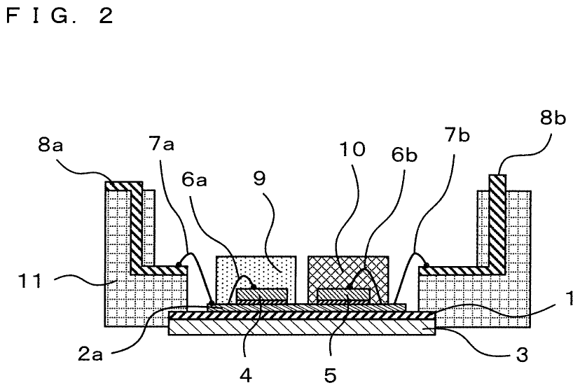

FIG. 2 is a schematic cross-sectional view of a semiconductor device according to Embodiment 2. As illustrated in FIG. 2, the semiconductor device according to Embodiment 2 differs from that according to Embodiment 1 in that the first sealant 9 is separated from the second sealant 10. Since the other structures are identical to those according to Embodiment 1, the detailed description is omitted. The separation between the first sealant 9 and the second sealant 10 can reduce mutual interference and application of stress even when one of the first sealant 9 and the second sealant 10 expands and contracts due to its curing in the manufacturing processes. Specifically, the separation can reduce deformation of the substrate and the casing which is caused by the expansion and contraction of the cured sealant.

Thus, application of the semiconductor device with such a structure can reduce mutual interference between sealants of the respective semiconductor elements as well as select a material of the sealant for each of the semiconductor elements without filling the sealant into the entire casing. Thus, the semiconductor device with improved humidity resistance in which deformation of the substrate and the casing caused by expansion and contraction of the cured sealants is further reduced can be obtained.

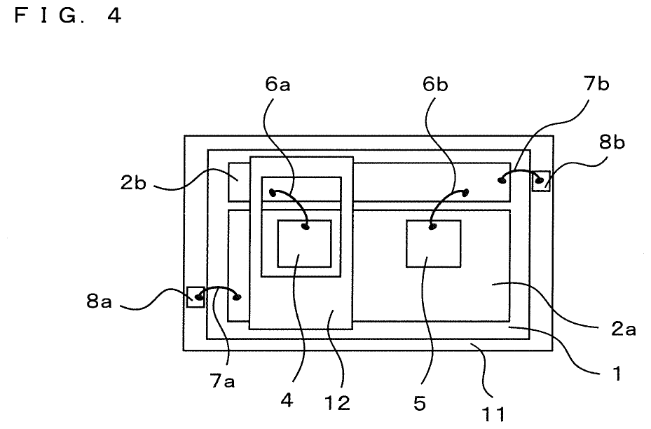

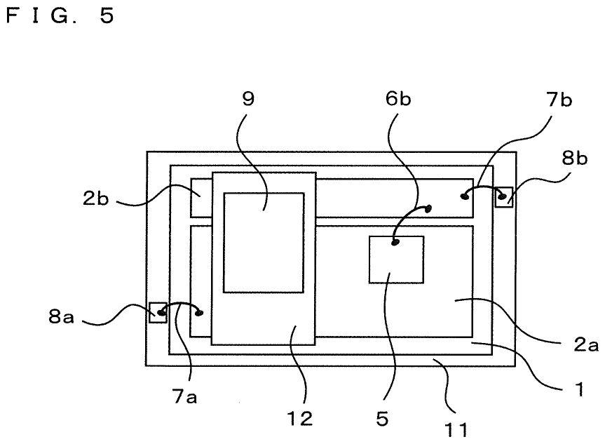

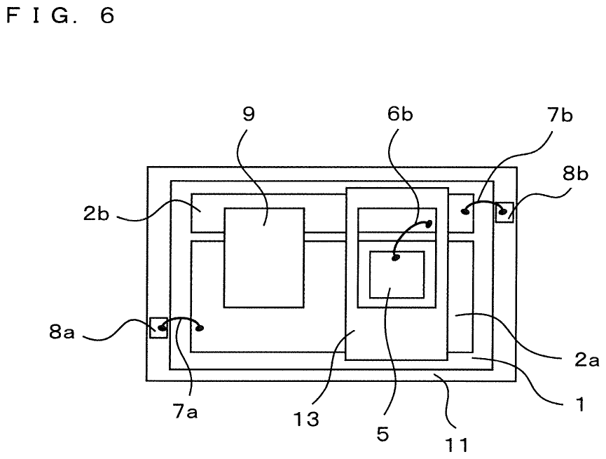

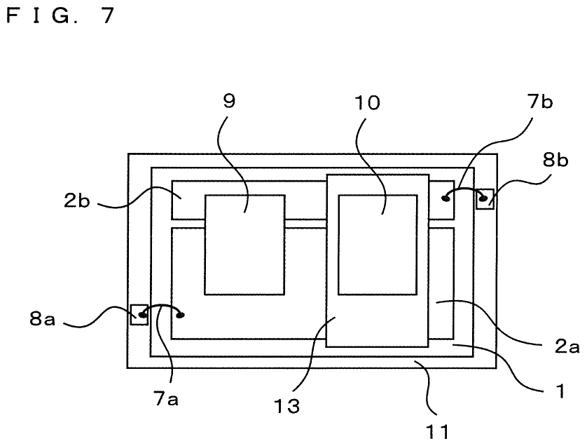

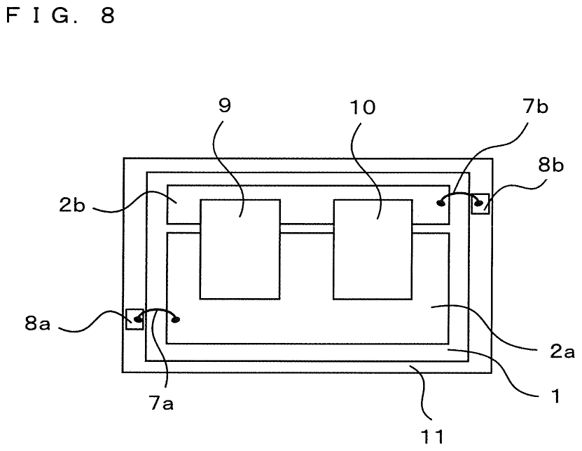

Here, processes for forming the first sealant 9 and the second sealant 10 in the semiconductor device according to Embodiment 2 will be schematically illustrated as an example. FIG. 3 is a schematic top view of the semiconductor device before the first sealant 9 and the second sealant 10 are formed according to Embodiment 2. FIG. 4 is a schematic top view of the semiconductor device in which a first jig 12 has been set, according to Embodiment 2. FIG. 5 is a schematic top view of the semiconductor device in which the first sealant 9 has been injected into the first jig 12, according to Embodiment 2. FIG. 6 is a schematic top view of the semiconductor device in which a second jig 13 has been set, according to Embodiment 2. FIG. 7 is a schematic top view of the semiconductor device in which the second sealant 10 has been injected into the second jig 13, according to Embodiment 2. FIG. 8 is a schematic top view of the semiconductor device after the first sealant 9 and the second sealant 10 have been formed, according to Embodiment 2.

For the sake of simplicity, the processes from a state immediately before the first sealant 9 and the second sealant 10 are formed will be described step by step. As illustrated in FIG. 3, the first semiconductor element 4 and the second semiconductor element 5 are mounted on the first circuit pattern 2a with the first semiconductor element 4 and the second semiconductor element 5 being exposed. First, to seal the first semiconductor element 4 with a plastic, the first jig 12 that delimits a region in which the first sealant 9 is formed is set, as illustrated in FIG. 4. Next, as illustrated in FIG. 5, the first sealant 9 is injected into the region enclosed by the first jig 12. After a curing treatment on the first sealant 9, the first jig 12 is removed. The curing treatment on the first sealant 9 is not particularly limited, but a curing treatment method such as irradiation of ultraviolet rays or heat treatment is applicable, depending on a sealant to be applied. Next, to seal the second semiconductor element 5 with a plastic, the second jig 13 that delimits a region in which the second sealant 10 is formed is set, as illustrated in FIG. 6. Next, as illustrated in FIG. 7, the second sealant 10 is injected into the region enclosed by the second jig 13. When the second jig 13 is removed after a curing treatment on the second sealant 10, the semiconductor device according to Embodiment 2 with the first sealant 9 being separated from the second sealant 10 is obtained, as illustrated in FIG. 8.

Thus, application of the semiconductor device according to Embodiment 2 can not only produce the advantages in Embodiment 1 but also reduce mutual interference between sealants of the respective semiconductor elements. Thus, the semiconductor device can produce an advantage of further reducing deformation of the substrate and the casing.

### Embodiment 3

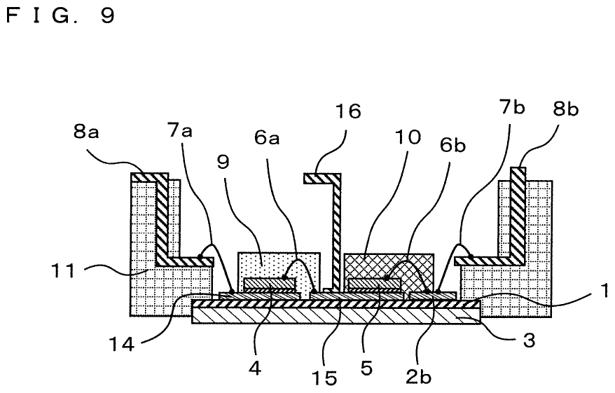

FIG. 9 is a schematic cross-sectional view of a semiconductor device according to Embodiment 3. As illustrated in FIG. 9, the semiconductor device according to Embodiment 3 differs from that according to Embodiment 1 in that a first circuit pattern includes a first semiconductor mounting circuit 14 and a second semiconductor mounting circuit 15, the first semiconductor element 4 is mounted on the first semiconductor mounting circuit 14, and the second semiconductor element 5 is mounted on the second semiconductor mounting circuit 15. The first semiconductor element 4 and the second semiconductor element 5 are electrically connected through the lead 6a, and a terminal electrode 16 is disposed between the first semiconductor element 4 and the second semiconductor element 5. Furthermore, the second semiconductor element 5 and the second circuit pattern 2b are electrically connected through the lead 6b. Since the other structures are identical to those according to Embodiment 1, the detailed description is omitted.

Application of the semiconductor device with such a structure enables selection of a material of a sealant for each of the semiconductor elements without filling the sealant into the entire casing, even in a semiconductor device in which three-pole operations are assumed. Thus, the semiconductor device with improved humidity resistance in which deformation of the substrate and the casing caused by expansion and contraction of the cured sealant is reduced can be obtained. Assume, for example, a power semiconductor device including the first semiconductor element 4 on the P side and the second semiconductor element 5 on the N side as illustrated in FIG. 9. The P side and the N side differ in, for example, type, operations, and characteristics of the semiconductor elements. Thus, selection of a sealant appropriate for each of the semiconductor elements greatly contributes to improvement in humidity resistance.

Thus, application of the semiconductor device according to Embodiment 3 can not only produce the advantages in Embodiment 1 but also select an appropriate sealant that accommodates differences in circuit structure. Thus, the semiconductor device with further improved humidity resistance can be obtained.

### Embodiment 4

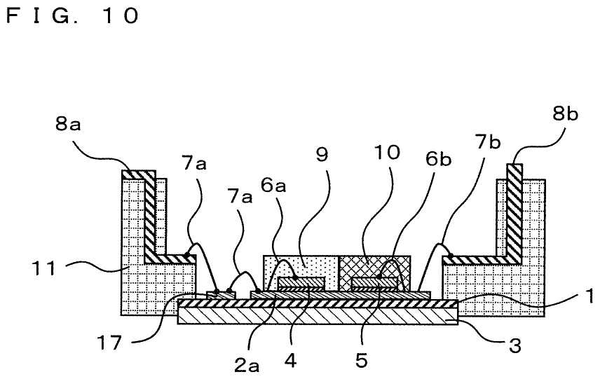

FIG. 10 is a schematic cross-sectional view of a semiconductor device according to Embodiment 4. As illustrated in FIG. 10, the semiconductor device according to Embodiment 4 differs from that according to Embodiment 1 in including a third circuit pattern 17 on which no semiconductor element is mounted, and in an electrical connection of the terminal electrode 8a to the first circuit pattern 2a through the control wire 7a and the third circuit pattern 17. Since the other structures are identical to those according to Embodiment 1, the detailed description is omitted.

Application of the semiconductor device with such a structure can increase the flexibility in the placement of semiconductor elements and designing a circuit pattern, and select a material of a sealant for each of the semiconductor elements without filling the sealant into the entire casing. Thus, the semiconductor device with improved humidity resistance in which deformation of the substrate and the casing caused by expansion and contraction of the cured sealant is reduced can be obtained. For example, when a semiconductor device has a circuit pattern for which avoidance of sealing with a sealant is desired, forming the circuit pattern as the third circuit pattern 17 in FIG. 10 can produce a semiconductor device with a circuit pattern that is not sealed with a sealant.

Thus, application of the semiconductor device according to Embodiment 4 can not only produce the advantages in Embodiment 1 but also increase the flexibility in the placement of semiconductor elements and designing a circuit pattern. Thus, the semiconductor device with further improved humidity resistance can be obtained.

### Embodiment 5

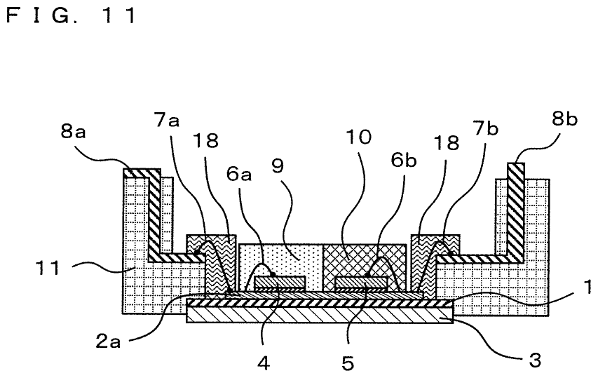

FIG. 11 is a schematic cross-sectional view of a semiconductor device according to Embodiment 5. As illustrated in FIG. 11, the semiconductor device according to Embodiment 5 differs from that according to Embodiment 1 in sealing the control wires 7a and 7b with a third sealant 18. Since the other structures are identical to those according to Embodiment 1, the detailed description is omitted. Although the third sealant 18 may be made of a material identical to that of the first sealant 9 or the second sealant 10, a material different from those of the first sealant 9 and the second sealant 10 or any material aimed at covering the control wires 7a and 7b is applicable to the material of the third sealant 18.

Application of the semiconductor device with such a structure can seal the control wires with the sealant, and enables selection of a material of a sealant for each semiconductor element without filling the sealant into the entire casing. Thus, the semiconductor device with improved humidity resistance in which deformation of the substrate and the casing caused by expansion and contraction of the cured sealant is reduced can be obtained.

Application of the semiconductor device according to Embodiment 5 can not only produce the advantages in Embodiment 1 but also cover the control wires with the sealant. Thus, the semiconductor device with further improved humidity resistance can be obtained.

### Embodiment 6

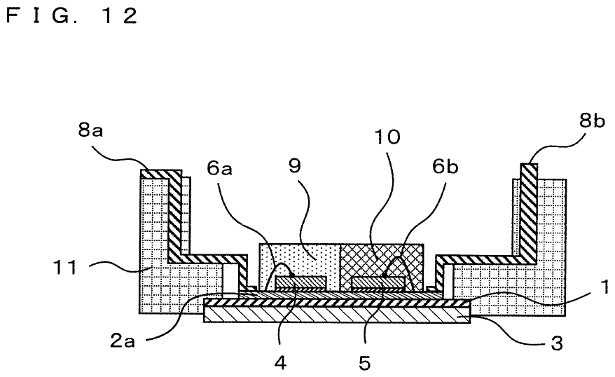

FIG. 12 is a schematic cross-sectional view of a semiconductor device according to Embodiment 6. As illustrated in FIG. 12, the semiconductor device according to Embodiment 6 differs from that according to Embodiment 1 in that the terminal electrode 8a is directly bonded to the first circuit pattern 2a and the terminal electrode 8b is directly bonded to the second circuit pattern 2b. Since the other structures are identical to those according to Embodiment 1, the detailed description is omitted. Any method such as thermal compression bonding, ultrasonic bonding, pulse heating, and laser heating is applicable to the direct bonding method. For example, when reduction in contact resistance and strong direct bonding are desired while a heat bonding method is avoided, application of the ultrasonic bonding is suitable.

Application of the semiconductor device with such a structure can reduce the contact resistance of a terminal electrode and improve the bonding stability. Further, the semiconductor device with improved humidity resistance in which deformation of the substrate and the casing caused by expansion and contraction of the cured sealant is reduced can be obtained.

Application of the semiconductor device according to Embodiment 6 can not only produce the advantages in Embodiment 1 but also reduce the contact resistance of a terminal electrode and improve the bonding stability. Thus, the semiconductor device with enhanced reliability can be obtained.

### Embodiment 7

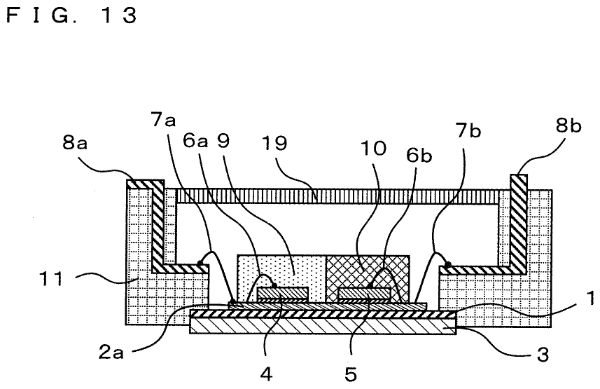

FIG. 13 is a schematic cross-sectional view of a semiconductor device according to Embodiment 7. As illustrated in FIG. 13, the semiconductor device according to Embodiment 7 differs from that according to Embodiment 1 in that the casing 11 includes a lid 19. Since the other structures are identical to those according to Embodiment 1, the detailed description is omitted.

Application of the semiconductor device with such a structure can provide protection and improve humidity resistance in the casing with the lid and enables selection of a material of a sealant for each semiconductor element without filling the sealant into the entire casing. Thus, the semiconductor device with improved humidity resistance in which deformation of the substrate and the casing caused by expansion and contraction of the cured sealant is reduced can be obtained. Furthermore, the lid can extend the range of design of semiconductor devices.

Thus, application of the semiconductor device according to Embodiment 7 can not only produce the advantages in Embodiment 1, but also provide protection and improve humidity resistance with the lid and obtain a semiconductor device with the extended range of design.

The following will describe a summary of various aspects of the present disclosure as appendixes.

Appendix 1 A semiconductor device comprising:
an insulating substrate;
a first circuit pattern formed on one surface of the insulating substrate;
a second circuit pattern formed on the one surface of the insulating substrate;
a first terminal electrode electrically connected to the first circuit pattern;
a first semiconductor element mounted on the first circuit pattern;
a second semiconductor element mounted on the first circuit pattern, the second semiconductor element being different from the first semiconductor element;
a second terminal electrode electrically connected to the first semiconductor element and the second semiconductor element through the second circuit pattern;
a first sealant covering the first semiconductor element;
a second sealant covering the second semiconductor element, the second sealant being made of a material different from a material of the first sealant; and
a casing enclosing the first semiconductor element and the second semiconductor element, the casing being separated from the first sealant and the second sealant and being bonded to the insulating substrate.
   Appendix 2 The semiconductor device according to appendix 1,
wherein a high-molecular-weight compound layer is formed on a surface of one of the first semiconductor element and the second semiconductor element, the high-molecular-weight compound layer being made of a material different from the materials of the first sealant and the second sealant.
   Appendix 3 The semiconductor device according to appendix 1 or 2,
wherein the first sealant is separated from the second sealant.
   Appendix 4 The semiconductor device according to one of appendixes 1 to 3,
wherein the first circuit pattern includes a first semiconductor mounting circuit on which the first semiconductor element is mounted, and a second semiconductor mounting circuit on which the second semiconductor element is mounted.
   Appendix 5 The semiconductor device according to appendix 4,
wherein the semiconductor device is a power semiconductor device, and
the first semiconductor mounting circuit is on a P side, and the second semiconductor mounting circuit is on an N side.
   Appendix 6 The semiconductor device according to one of appendixes 1 to 5,
wherein the first circuit pattern is electrically connected to the first terminal electrode through a third circuit pattern on which no semiconductor element is mounted.
   Appendix 7 The semiconductor device according to appendix 6,
wherein the third circuit pattern is not covered with a sealant.
   Appendix 8 The semiconductor device according to one of appendixes 1 to 7,
wherein the first terminal electrode is electrically connected to the first circuit pattern through a first control wire, and the second terminal electrode is electrically connected to the second circuit pattern through a second control wire, and
the first control wire and the second control wire are covered with a third sealant.
   Appendix 9 The semiconductor device according to appendix 8,
wherein the third sealant is made of a material different from the materials of the first sealant and the second sealant.
   Appendix 10 The semiconductor device according to one of appendixes 1 to 9,
wherein at least one of the electrical connection of the first terminal electrode to the first circuit pattern or the electrical connection of the second terminal electrode to the second circuit pattern is an electrical connection through direct bonding.
   Appendix 11 The semiconductor device according to appendix 10,
wherein the at least one of the electrical connection of the first terminal electrode to the first circuit pattern or the electrical connection of the second terminal electrode to the second circuit pattern is an electrical connection through ultrasonic bonding as the direct bonding.
   Appendix 12 The semiconductor device according to one of appendixes 1 to 11,
wherein the casing includes a lid.
While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
an insulating substrate;
a first circuit pattern formed on one surface of the insulating substrate;
a second circuit pattern formed on the one surface of the insulating substrate;
a first terminal electrode electrically connected to the first circuit pattern;
a first semiconductor element mounted on the first circuit pattern;
a second semiconductor element mounted on the first circuit pattern, the second semiconductor element being different from the first semiconductor element;
a second terminal electrode electrically connected to the first semiconductor element and the second semiconductor element through the second circuit pattern;
a first sealant covering the first semiconductor element;
a second sealant covering the second semiconductor element, the second sealant being made of a material different from a material of the first sealant; and
a casing enclosing the first semiconductor element and the second semiconductor element, the casing being separated from the first sealant and the second sealant and being bonded to the insulating substrate.

2. The semiconductor device according to claim 1,
wherein a high-molecular-weight compound layer is formed on a surface of one of the first semiconductor element and the second semiconductor element, the high-molecular-weight compound layer being made of a material different from the materials of the first sealant and the second sealant.

3. The semiconductor device according to claim 1,
wherein the first sealant is separated from the second sealant.

4. The semiconductor device according to claim 1,
wherein the first circuit pattern includes a first semiconductor mounting circuit on which the first semiconductor element is mounted, and a second semiconductor mounting circuit on which the second semiconductor element is mounted.

5. The semiconductor device according to claim 4,
wherein the semiconductor device is a power semiconductor device, and
the first semiconductor mounting circuit is on a P side, and the second semiconductor mounting circuit is on an N side.

6. The semiconductor device according to claim 1,
wherein the first circuit pattern is electrically connected to the first terminal electrode through a third circuit pattern on which no semiconductor element is mounted.

7. The semiconductor device according to claim 6,
wherein the third circuit pattern is not covered with a sealant.

8. The semiconductor device according to claim 1,
wherein the first terminal electrode is electrically connected to the first circuit pattern through a first control wire, and the second terminal electrode is electrically connected to the second circuit pattern through a second control wire, and
the first control wire and the second control wire are covered with a third sealant.

9. The semiconductor device according to claim 8,
wherein the third sealant is made of a material different from the materials of the first sealant and the second sealant.

10. The semiconductor device according to claim 1,
wherein at least one of the electrical connection of the first terminal electrode to the first circuit pattern or the electrical connection of the second terminal electrode to the second circuit pattern is an electrical connection through direct bonding.

11. The semiconductor device according to claim 10,
wherein the at least one of the electrical connection of the first terminal electrode to the first circuit pattern or the electrical connection of the second terminal electrode to the second circuit pattern is an electrical connection through ultrasonic bonding as the direct bonding.

12. The semiconductor device according to claim 1,
wherein the casing includes a lid.
